(19) United States
(12) Patent Application Publication
(10) Pub. No.: US 2021/0346851 A1
(43) Pub. Date: Nov. 11, 2021

(54) LIQUID PRECURSOR BUBBLER

(71) Applicant: William L. Kimmerle, Hudson, OH (US)

(72) Inventor: William L. Kimmerle, Hudson, OH (US)

(21) Appl. No.: 17/000,871

(22) Filed: Aug. 24, 2020

Related U.S. Application Data
(60) Provisional application No. 63/021,409, filed on May 7, 2020.

(51) Int. Cl. B01F 3/02; B01F 15/00; B01F 5/06

(52) U.S. Cl. CPC B01F 3/022; C23C 16/4482; B01F 5/0606; B01F 15/00889

(57) ABSTRACT

One or more techniques and/or systems are disclosed for saturating a gas with a liquid-borne compound. A bubbler container may be configured to contain a carrier liquid, which comprises a desired compound. The container may comprise at least one channeling plane, disposed between the top and bottom of the container, which may be configured to allow gas bubbles to travel through a circuitous, channeling route. The gas can be introduced to the container at a bottom portion of the container, into the carrier liquid comprising the compound. Carrier gas bubbles formed in the liquid may be forced to travel the channeling route to a top portion of the container, where gas saturated with the compound may be collected.

### CROSS-REFERENCE TO RELATED APPLICATIONS

This application claims priority to U.S. Provisional Patent Application Ser. No. 63/021,409, entitled LIQUID PRECURSOR BUBBLER, filed May 7, 2020, which is incorporated herein by reference

Apparatuses and systems for generating a carrier gas stream containing a desired compound, under controlled environment conditions, are used in a variety of industries. For example, “bubblers” are often used in the electronics fabrication industry, particularly when manufacturing semiconductors, integrated circuits, computer chips and LEDs. A carrier gas saturated with the desired compound (e.g., in vapor form) may be delivered to processing equipment that provides for deposition of the compound to form layers and/or films, for example. The carrier gas may be saturated with the desired compound by “bubbling” it through a liquid or solid precursor that comprises the desired compound.

Sometimes, in order to achieve a desired carrier gas pressure, flow, and/or compound vapor concentrations, a higher gas flow rate may be used in a bubbler. When higher gas flow rates are used in liquid bubblers, splashing of the liquid and/or a less than desired saturation-rate of the liquid-borne compound in the gas may occur. Further, for example, increasing a carrier gas flow rate in a bubbler (e.g., which can increase as a liquid level in the bubbler decreases) can result in lower gas-phase concentration of the liquid-borne compound in the carrier gas stream exiting the bubbler. The lower saturation rate and/or decreased gas-phase concentration may be due to a lower carrier gas exposure time in the precursor carrier liquid. Additionally, an increase in splashing and churning of the liquid can lead to generation of suspended liquid-phase droplets, which may cause problems with compound concentration control, clogging, and/or problems with the bubbler system.

### SUMMARY

This Summary is provided to introduce a selection of concepts in a simplified form that are further described below in the Detailed Description. This Summary is not intended to identify key factors or essential features of the claimed subject matter, nor is it intended to be used to limit the scope of the claimed subject matter.

Accordingly, among other things, one or more techniques and/or systems are disclosed for saturating a gas with a desired compound (e.g., in gas-phase and/or as a vapor), such as a metalorganic compound, at a preferred saturation and/or consumption rate, while mitigating a splashing and/or churning of a carrier liquid comprising the desired compound. Further, the saturation rate may be improved even at higher gas flow rates. For example, a gas to liquid exposure time may be increased by forcing carrier gas bubbles to travel along a deviating, channeling path from the bottom of a bubbler container to the top of the bubbler container. Additionally, channeling plates that form the deviating path may also force the carrier liquid along the channels, providing the gas with additional time of exposure to the liquid, especially at a higher flow rate of the carrier gas, for example.

In one implementation of an apparatus for saturating a gas with a liquid-borne compound, a container can comprise a first channeling plane that may be disposed between the bottom of the container and the top of the container. In this implementation, the container may be configured to contain a carrier liquid comprising the compound. The container may be further configured to allow the gas to flow into the container at a bottom portion of the container and flow out of the container at a top portion of the container.

In one implementation of a method for saturating a gas with a liquid-borne compound, the gas can be introduced to a container at a bottom portion of the container. In this implementation, the container can comprise a carrier liquid comprising the compound, and a first channeling plane that may be resident between the bottom of the container and the top of the container. Further, in this implementation, the gas can be collected at a top portion of the container.

To the accomplishment of the foregoing and related ends, the following description and annexed drawings set forth certain illustrative aspects and implementations. These are indicative of but a few of the various ways in which one or more aspects may be employed. Other aspects, advantages and novel features of the disclosure will become apparent from the following detailed description when considered in conjunction with the annexed drawings.

### BRIEF DESCRIPTION OF THE DRAWINGS

FIGS. 1A and 1B are component diagrams illustrating an exemplary apparatus for saturating a gas with a liquid-borne compound.

FIGS. 2A and 2B are component diagrams illustrating example implementations where one or more portions of one or more apparatuses described herein may be implemented.

FIGS. 3A and 3B are component diagrams illustrating example implementations where one or more portions of one or more apparatuses described herein may be implemented.

FIG. 4 is a component diagram illustrating an example implementation where one or more portions of one or more apparatuses described herein may be implemented.

FIG. 5 is a component diagram illustrating an example implementation where one or more portions of one or more apparatuses described herein may be implemented.

FIG. 6 is a component diagram illustrating an example implementation where one or more portions of one or more apparatuses described herein may be implemented.

FIG. 7 is a component diagram illustrating an example implementation where one or more portions of one or more apparatuses described herein may be implemented.

FIG. 8 is a component diagram illustrating an example implementation where one or more portions of one or more apparatuses described herein may be implemented.

FIGS. 9A, 9B, and 9C are component diagrams illustrating example implementations where one or more portions of one or more apparatuses described herein may be implemented.

FIGS. 10A and 10B are component diagrams illustrating example implementations where one or more portions of one or more apparatuses described herein may be implemented.

FIG. 11 is a flow diagram illustrating an exemplary method for saturating a gas with a liquid-borne compound.

### DETAILED DESCRIPTION

The claimed subject matter is now described with reference to the drawings, wherein like reference numerals are generally used to refer to like elements throughout. In the following description, for purposes of explanation, numerous specific details are set forth in order to provide a thorough understanding of the claimed subject matter. It may be evident, however, that the claimed subject matter may be practiced without these specific details. In other instances, structures and devices are shown in block diagram form in order to facilitate describing the claimed subject matter.

Traditionally, precursor delivery bubblers exhibit undesirable properties at higher gas flow rates, such as splashing of the liquid and/or poor saturation of the carrier gas by the liquid (e.g., as a vapor). That is, for example, the saturation rate of the liquid-borne compound, such as a metalorganic compound (e.g., Trimethyl gallium (TMG), into the carrier gas may decline sharply well before most of the liquid-borne compound has been consumed from the precursor carrier liquid. Further, for example, increasing a carrier gas flow rate in a bubbler can result in lower gas-phase concentration of the liquid-borne compound in the carrier gas stream exiting the bubbler

The lower saturation rate and/or decreased gas-phase concentration may be due to an increased bubble diameters resulting from increased pressure for a given sparger tube outlet, as well as a resulting decrease in carrier gas exposure time in the carrier liquid (e.g., carrying the metalorganic compound). Additionally, an increase in splashing and churning of the liquid can lead to generation of suspended liquid-phase droplets, which can become entrained in the carrier gas flow exiting the bubbler. Subsequent deposition of these droplets downstream of the bubbler may create additional problems, such as contamination and/or poor control of the gas-phase concentration of a resulting chemical vapor (e.g., the carrier gas comprising the liquid-borne compound).

As provided herein, an apparatus may be devised that provides for saturating a gas with a liquid-borne compound, for example, at a desired saturation and/or consumption rate, while mitigating a splashing and/or churning of a liquid comprising the desired compound. As one example, an exposure time may be increased by forcing the carrier gas to travel along a deviating path from the bottom of a bubbler container to the top of the bubbler container. Further, by utilizing channels to create the deviating path, the precursor liquid comprising the desired compound may also be forced up, along the channels, providing the gas with additional time of exposure to the liquid (e.g., and therefore the liquid-borne compound), especially at a higher flow rate of the carrier gas, for example.

In one implementation, a high flow rate bubbler may comprise a container that is configured to allow a gas, such as a carrier gas (e.g., hydrogen (H₂) or nitrogen (N₂)), to enter at a bottom portion of the container and exit at a top portion of the container. That is, for example, the container may comprise an inlet tube that is configured as a type of “dip-tube,” where the carrier gas flow can be directed to the bottom of the container, such that “bubbles” of the carrier gas are introduced to a liquid comprising the desired compound to be transferred (e.g., saturated) to the gas. In this example, the liquid may be disposed at the bottom of the container (e.g., to a desired level), and the gas can be introduced at the bottom of the container (e.g., substantially adjacent to a bottom plane and/or point of the container), through the liquid.

In one implementation, the inlet tube may comprise a type of sparger tube outlet. In this implementation, for example, the sparger tube outlet may be configured to produce gas bubbles that have a diameter within a desired diameter range. As an example, the sparger tube outlet may be configured to produce a desired sized bubble at a desired gas flow rate (e.g., a high flow rate). In this example, the desired sized bubble may result in a more efficient transfer of the liquid-borne compound to the carrier gas than other sized bubbles, at the desired flow rate.

In one implementation, the bubbler container may comprise a first channeling plane that resides between the bottom portion of the container and the top portion of the container. As one example, the first channeling plane can comprise a type of plate that transects the container, dividing the bottom portion from the top portion. In one implementation, the first channeling plane may comprise a channel opening at a first side of the plane, where the channel opening may be configured (e.g., sized and/or shaped) to allow passage of a flow of carrier gas bubbles from below the plane to above the plane.

That is, for example, the intersection of the channeling plane and an interior side of the bubbling container may be sealed to mitigate flow of gas and/or liquid at that intersection. Further, in this example, a portion of the channeling plane comprising the channel opening may not intersect the interior side of the bubbling container, thereby providing a channel for the flow of the carrier gas and/or compound containing liquid. As another example, where the intersection of the channeling plane and the interior side of the bubbling container is sealed at respective sides, the channel opening may comprise one or more sections “cut-out” from channeling plane at a channeling area of the channeling plane.

In one implementation, the bubbler container may comprise a plurality of channeling planes residing between the bottom portion of the container and the top portion of the container. As one example, a desired number of channeling planes may be resident in the container, where the channeling planes can be configured to direct the flow of gas and/or liquid in a desired channeling route inside the container. For example, the gas may be introduced to the container at a second side of the bottom portion of the container, and the first channeling plane may comprise a channel opening at the first side of the container. Further, in this example, a second channeling plane may be resident above the first channeling plate and may comprise a channel opening at the second side of the container. Additionally, in this example, a gas exit opening may be resident at the top portion, at the first side of the container.

In this example, when the gas is introduced to the bottom portion of the container, the gas bubbles can travel to the second side, through the channel opening in the first channeling plane, back to the first side, through the channel opening in the second plane, and back again to the second side to the exit opening. In this way, for example, the gas bubbles that may be released at the bottom of the container can travel a deviating (e.g., a circuitous and longer) route through the liquid, thereby exposing the bubbles to the liquid for a longer period of time than if they were to merely travel straight from the bottom to the top.

Further, as one example, at a higher gas flow rate, a force on the liquid may be substantially proportional to a flux of the gas bubbles; and the gas may behave more like a liquid (e.g., having a higher viscosity than merely the gas by itself). In this way, in this example, the liquid may be moved in the direction of the bubble flow to equalize the forces. Therefore, in this example, the gas bubbles can help force the liquid through the channeling route created by the channeling planes. By moving the liquid further through the channels and up the container, for example, the gas bubbles may also be exposed to the liquid for a longer period, thereby providing improved saturation of the precursor (e.g., metalorganic compound) to the gas (e.g., carrier gas).

In one implementation, the first channeling plane (e.g., and one or more of the respective other channeling planes, if present) may comprise one or more vias (e.g., slots, slits and/or holes). As one example, the respective one or more vias may comprise an opening configured to mitigate passage of gas bubbles (e.g., at the desired bubble diameter, given the desired gas flow rate), and/or configured to allow passage of the liquid through the via.

That is, for example, at a desired gas flow rate, the liquid may be able to move along the channeling route and/or through the vias, while the bubbles may merely move along the channeling route. In this way, for example, the bubbles may still be forced to travel the circuitous channeling route to increase exposure time (e.g., and therefore saturation), while the liquid can travel upward in the container through both the channeling route and the vias (e.g., which can also facilitate increasing the exposure time for the gas to the liquid).

Bubbles flowing in the liquid may coalesce to form larger bubbles, for example, which may lessen a gas to liquid exposure (e.g., reducing gas saturation). For example, a trailing bubble may travel faster than a leading bubble in the wake of the leading bubble, causing the trailing bubble to merge with the leading bubble. In a turbulent liquid environment and/or a faster flow rate, for example, this effect may be mitigated. In one implementation, in order to provide for a faster flow rate and/or a turbulent environment, the channeling planes may be adjusted.

In one implementation, the first channeling plane (e.g., and respective other channeling planes, if present) may be disposed at a divergent angle to the plane of the bottom wall, and/or top wall of the container. That is, for example, the respective one or more channeling planes resident in the container may be angled up and or down to facilitate a desired flow (e.g., faster flow) of the carrier gas bubbles through the carrier liquid. In one implementation, a turbulence insert (e.g., a coil, spring and/or appendage(s)) may be added to a channeling plane, and/or in the channel route. As an example, one or more “shark-tooth” appendages may be attached to an underside of the respective channeling planes, such as substantially at an end (e.g., in a channel opening). As another example, a wire coil may be placed in the channel route, such as between respective channeling planes.

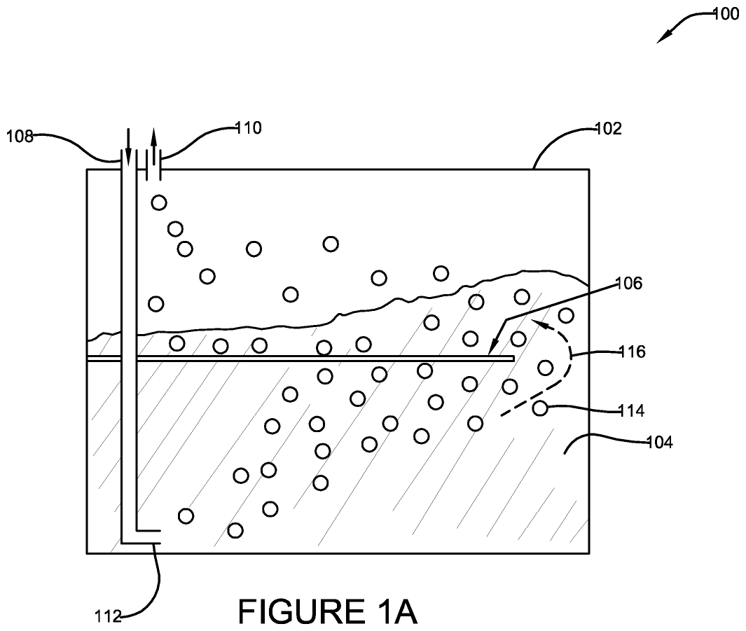

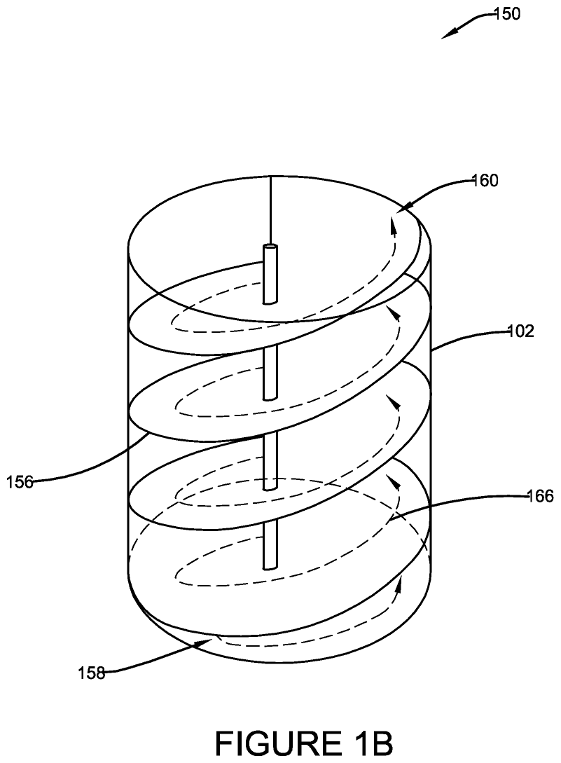

FIG. 1A is a component diagram illustrating an exemplary apparatus 100 for saturating a gas with a liquid-borne compound. As shown in the exemplary apparatus 100, a container 102 is configured to contain a carrier liquid 104 that comprises a desired compound. In this exemplary apparatus 100, the container 102 comprises a channeling plane 106, which is disposed between the bottom and top of the container 102. Further, a carrier gas inlet 108 allows the carrier gas to flow into the container 102, and a carrier gas outlet 110 allows the carrier gas to flow out of the container 102.

As an example, the carrier gas may be introduced to the liquid 104 by a dip tube opening 112 disposed at the bottom of the container 102. Carrier gas bubbles 114 may be formed in the liquid, where the bubbles comprise a diameter within a desired bubble diameter range (e.g., based on the gas flow rate and/or sparger tube configuration). In this example, due to the presence of the channeling plane 106, the carrier gas bubbles 114 can be forced along a channeling route 116, which may comprise a longer route of travel than without the channeling plane 106. In this way, the carrier gas bubbles 114 may have a longer exposure time to the liquid 104, thereby providing for increased saturation of the desired compound from the carrier liquid 104 to the carrier gas (e.g., saturated carrier gas). As one example, the channeling plane may attached (e.g., welded and/or attached in any other suitable means provided for by the container and/or plane materials) to an interior wall of container, such as at an opposing direction to the wall.

FIG. 1B is a component diagram illustrating an example implementation 150 where one or more portions of one or more apparatuses described herein may be implemented. In this example 150, an extension of FIG. 1 is provided and thus description of elements, components, etc. described with respect to FIG. 1 may not be repeated for simplicity. In this implementation 150, the container 102 comprises a channeling plane 156, which is disposed between the bottom and top of the container 102. Further, channeling plane 156 is configured in a type of spiral assembly. As one example, the spiral assembly of the channeling plane may provide for a gas flow 166 that travels in a spiral from an inlet area 158 at the bottom to an outlet 160 at the top of the container 102. In this way, for example, the carrier gas may travel a longer route through a carrier liquid, thereby providing for increased saturation of the desired compound from the carrier liquid to the carrier gas.

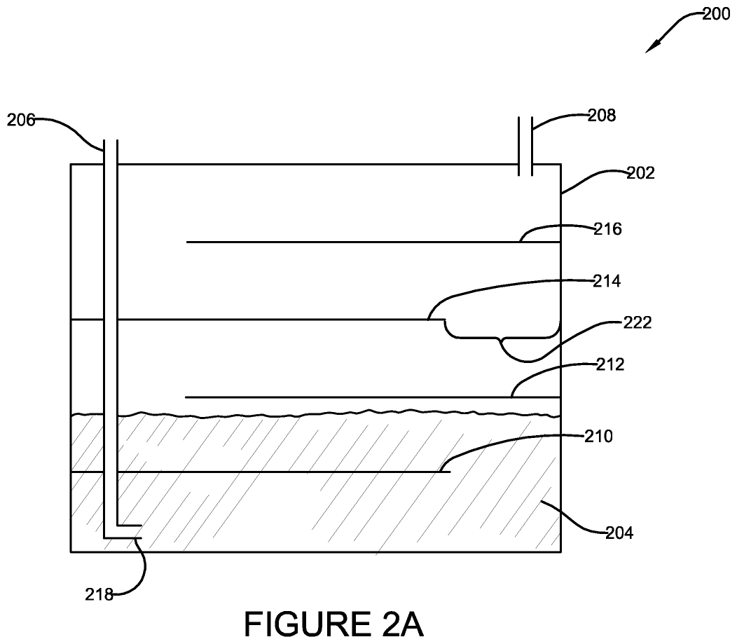

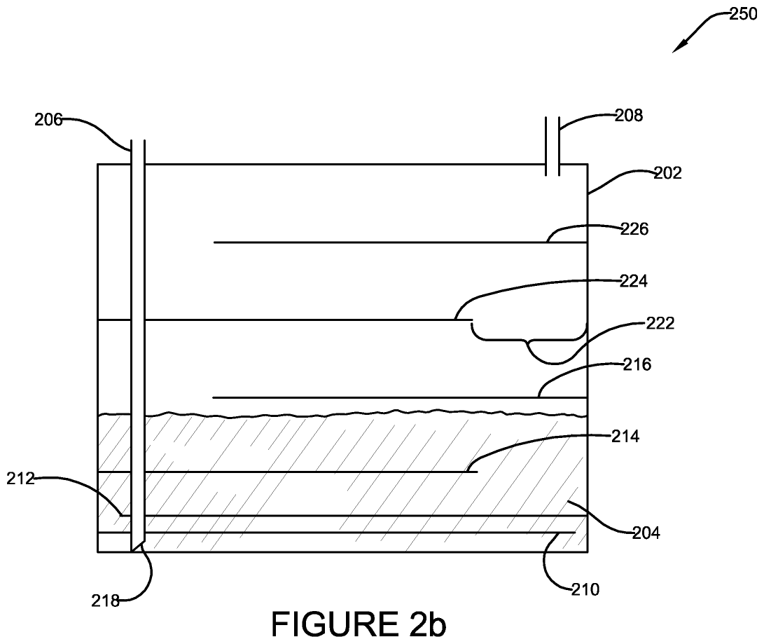

FIG. 2A is a component diagram illustrating an example implementation 200 where one or more portions of one or more apparatuses described herein may be implemented. In this implementation 200, a container 202 is configured to contain a carrier liquid 204 that comprises a desired compound to be saturated into a carrier gas. The container 202 further comprises a gas inlet 206, for introducing the carrier gas to the liquid 204, having a dip-tube opening 218 at the bottom of the container 202; and a gas outlet 208, for example, for collecting the carrier gas saturated with the desired compound. Further, in this implementation 200, the container 202 comprises a first channeling plane 210, a second channeling plane 212, a third channeling plane 214, and a fourth channeling plane 216. Respective channeling planes 210, 212, 214, 216 can comprise a channel opening 222, for example, which may be configured to allow passage of the carrier gas and/or carrier liquid 204, such as along a channeling route.

FIG. 2B is a component diagram illustrating an example implementation 250 where one or more portions of one or more apparatuses described herein may be implemented. In this implementation 250, the dip-tube opening 218 at the bottom of the container 202 may be configured to be substantially adjacent to a bottom wall of the container 202, for example, such that when the gas is introduced into the container 202 bubbles may be formed immediately adjacent to the bottom wall. Further, for example, a smaller sized bubble may be formed when the dip-tube opening 218 is disposed immediately adjacent to the bottom of the container 202. Additionally, in this example 250, the first channeling plane 210 may be disposed immediately adjacent to, and above, the dip-tube opening 218. In one implementation, a distance between the first channeling plane 210 and the second channeling plane 212 (e.g., and the second and third, and/or the third and fourth) may be configured to merely accommodate a size of a bubble released from the dip-tube opening 218.

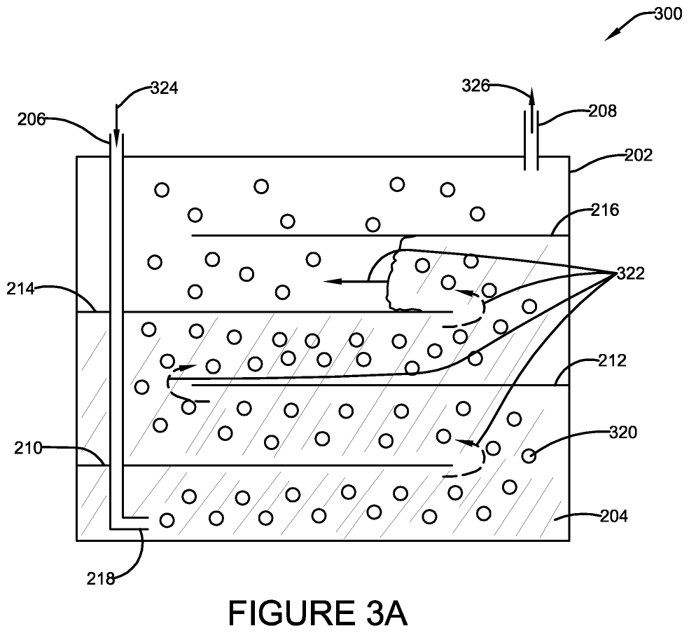

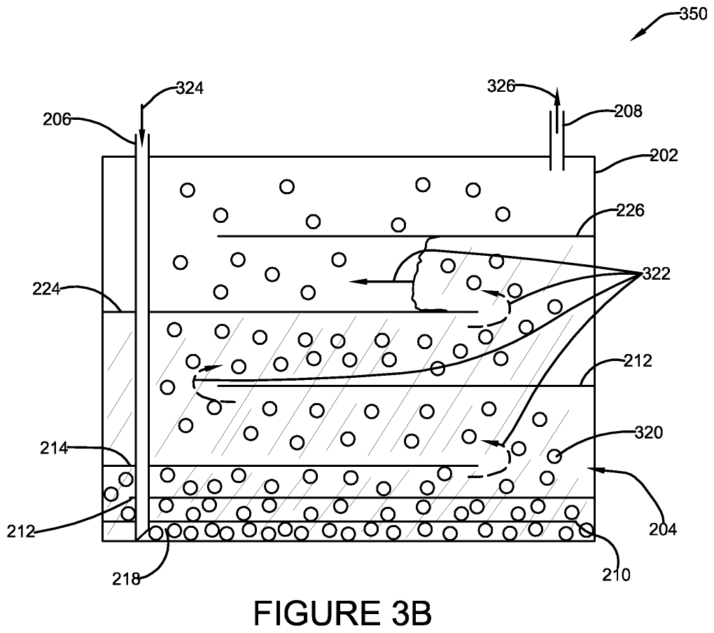

FIG. 3A is a component diagram illustrating an example implementation 300 where one or more portions of one or more apparatuses described herein may be implemented. In this example 300, an extension of FIG. 2A is provided and thus description of elements, components, etc. described with respect to FIG. 2A may not be repeated for simplicity. In the example implementation 300, a carrier gas can be introduced 324 at the inlet 206, which, in turn, may release carrier gas bubbles 320 into the liquid 204 from the dip-tube opening 218 at the bottom of the container 202. The carrier gas bubbles 320 are forced to travel along a channeling route 322 to the outlet 208, where the saturated carrier gas may be collected 326. Further, the introduction of the carrier gas to the liquid 204 may force the liquid 204 along the channeling route, further up in the container 202 (e.g., higher than without the channeling planes 210, 212, 214, 216). Forcing the carrier gas bubbles 320 along the channeling route 322, and/or moving the liquid 204 further up the container 202 can allow for greater (e.g., longer, more) exposure of the carrier gas to the liquid 204 comprising the desired compound for a longer period, thereby increasing compound saturation to the carrier gas.

FIG. 3B is a component diagram illustrating an example implementation 200 where one or more portions of one or more apparatuses described herein may be implemented. In this implementation 350, when the carrier gas is introduced 324 at the inlet 206, it causes carrier gas bubbles 320 to be release into the liquid 204 from the dip-tube opening 218 at the bottom of the container 202. Due to the proximity of the dip-tube opening 218 to the bottom of the container 202, for example, the carrier gas bubbles may be of a desirable, smaller size. Further, the carrier gas bubbles 320 travel along the channeling route 322, in a confined area created by the first channeling plane, the second channeling plane 212, etc. In this way, for example, the channeling route 322 may be increased, and/or an exposure of the gas to the liquid may be increased.

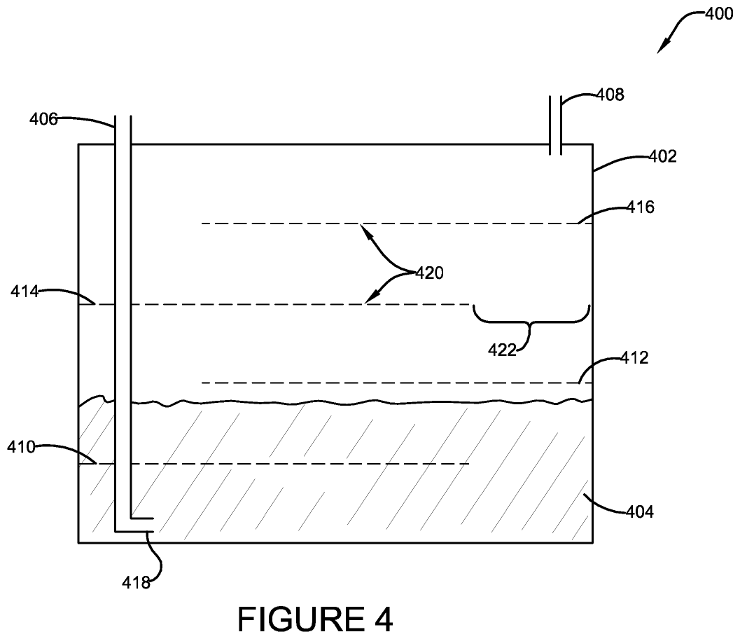

FIG. 4 is a component diagram illustrating an example implementation 400 where one or more portions of one or more apparatuses described herein may be implemented. In this example 400, a container 402 is configured to contain a carrier liquid 404 that can comprise a desired compound to be saturated into a carrier gas. The container 402 can further comprise a gas inlet 406, for introducing the carrier gas to the liquid 404, having a dip-tube opening 418 at the bottom of the container 402; and a gas outlet 408, for example, for collecting the carrier gas saturated with the desired compound.

Further, in this implementation 400, the container 402 comprises a first channeling plane 410, a second channeling plane 412, a third channeling plane 414, and a fourth channeling plane 416. Respective channeling planes 410, 412, 414, 416 can comprise a channel opening 422, for example, which may be configured to allow passage of the carrier gas and/or carrier liquid 404, such as along a channeling route. Additionally, in this implementation 400, the respective channeling planes 410, 412, 414, 416 can comprise one or more vias 420, which may be configured to merely allow passage of liquid across the via 420; and may be configured to mitigate passage of carrier gas bubbles.

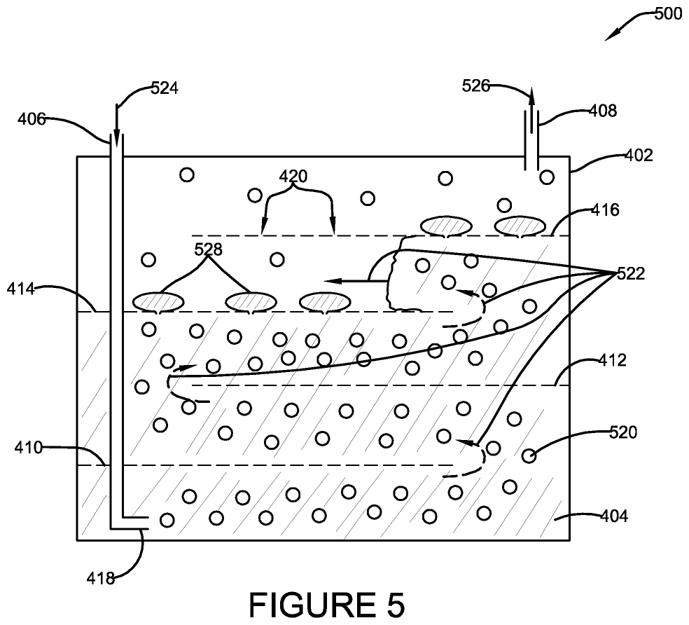

FIG. 5 is a component diagram illustrating an example implementation 500 where one or more portions of one or more apparatuses described herein may be implemented. In this example 500, an extension of FIG. 4 is provided and thus description of elements, components, etc. described with respect to FIG. 4 may not be repeated for simplicity. In the example implementation 500, a carrier gas can be introduced 524 at the inlet 406, which, in turn, may release carrier gas bubbles 520 into the liquid 404 from the dip-tube opening 418 at the bottom of the container 402. The carrier gas bubbles 520 are forced to travel along a channeling route 522 to the outlet 408, where the saturated carrier gas may be collected 526.

Further, the introduction of the carrier gas to the liquid 404 may force the liquid 404 along the channeling route and/or through the one or more vias 420, causing the liquid 404 to splash above the channeling planes 410, 412, 414, 416. For example, this action can force the liquid 404 further up in the container 402, which may provide for longer exposure to the carrier gas. However, in this implementation 500, the gas bubbles may not be able to flow through the vias 420, forcing the carrier gas bubbles 520 along the channeling route 522, which can also allow for greater exposure of the carrier gas to the liquid 404 comprising the desired compound, thereby increasing compound saturation to the carrier gas.

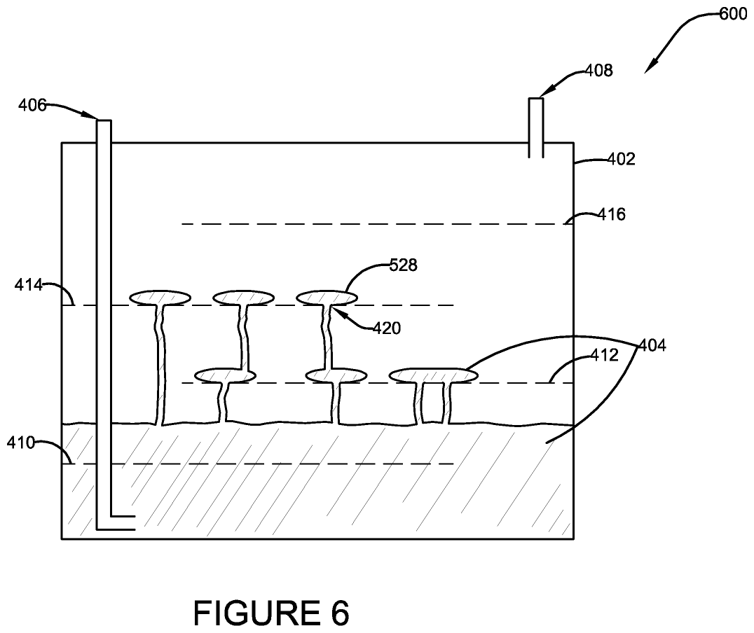

FIG. 6 is a component diagram illustrating an example implementation 600 where one or more portions of one or more apparatuses described herein may be implemented. In this example 600, an extension of FIGS. 4 and 5 is provided and thus description of elements, components, etc. described with respect to FIGS. 4 and 5 may not be repeated for simplicity. In the example implementation 600, the flow of carrier gas into the inlet 406 and out through the outlet 408 has been shut off. Upon shutting off the flow of gas into the liquid, the force that may have moved the bubble/liquid mix up the container 402, such as along the channeling route, may also diminish. Once the liquid is no longer forced up the container, liquid 404 that may have been splashed 528 over the channeling planes 410, 412, 414, 416 may flow back to the bottom of the container 402 through the vias 420.

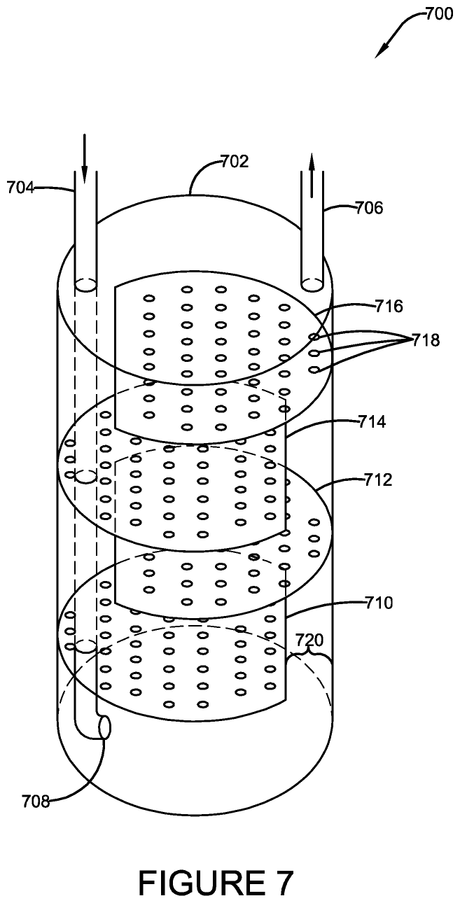

FIG. 7 is a component diagram illustrating an example implementation 700 where one or more portions of one or more apparatuses described herein may be implemented. In this implementation 700, the bubbling container 702 is configured to contain a carrier liquid comprising a desired compound (not shown), such as a metalorganic compound-based liquid. The container 702 comprises a carrier gas inlet 704, through which the carrier gas may be introduced into the container 702. A dip-tube type opening 708 is disposed at a bottom portion of the container 702, and is configured to introduce the carrier gas into the carrier liquid, which may reside at the bottom of the container 702 (e.g., when filled). The container 702 further comprises a carrier gas outlet 706, through which the carrier gas may be collected from the container 702, for example, where it may be saturated with the desired compound (e.g., metalorganic compound) from the carrier liquid.

In this implementation 700, a series of channeling planes 710, 712, 714, 716 are disposed between the bottom and top of the container 702. Further, respective channeling planes 710, 712, 714, 716 comprise a channel opening 720, which can be configured to allow for the carrier liquid and/or the carrier gas to flow from below a channeling plane 710, 712, 714, 716 to above the channeling plane 710, 712, 714, 716. For example, the respective channel openings 720 may provide a channeling route for the carrier liquid and/or the carrier gas to flow around the channeling planes 710, 712, 714, 716. Additionally, in the respective channeling planes 710, 712, 714, 716 comprise a plurality of vias 718, which may be configured to mitigate passage of carrier gas bubbles to flow across the via 718, but may allow for the carrier liquid to flow across the via 718.

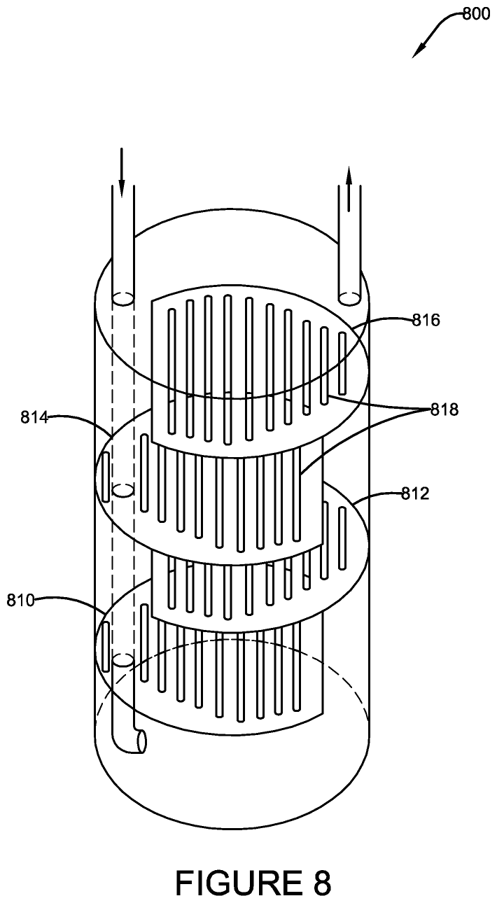

FIG. 8 is a component diagram illustrating an example implementation 800 where one or more portions of one or more apparatuses described herein may be implemented. In this implementation 800, the vias 818 comprise slits and/or slots across the respective channeling planes 810, 812, 814, 816. In this implementation, the vias 818 are configured to mitigate passage of carrier gas bubbles to flow across the via 818, but may allow for the carrier liquid to flow across the via 818. In this way, for example, the carrier gas may be forced around the channeling planes 810, 812, 814, 816, while the carrier liquid can travel through the channeling planes 810, 812, 814, 816, across the vias 818.

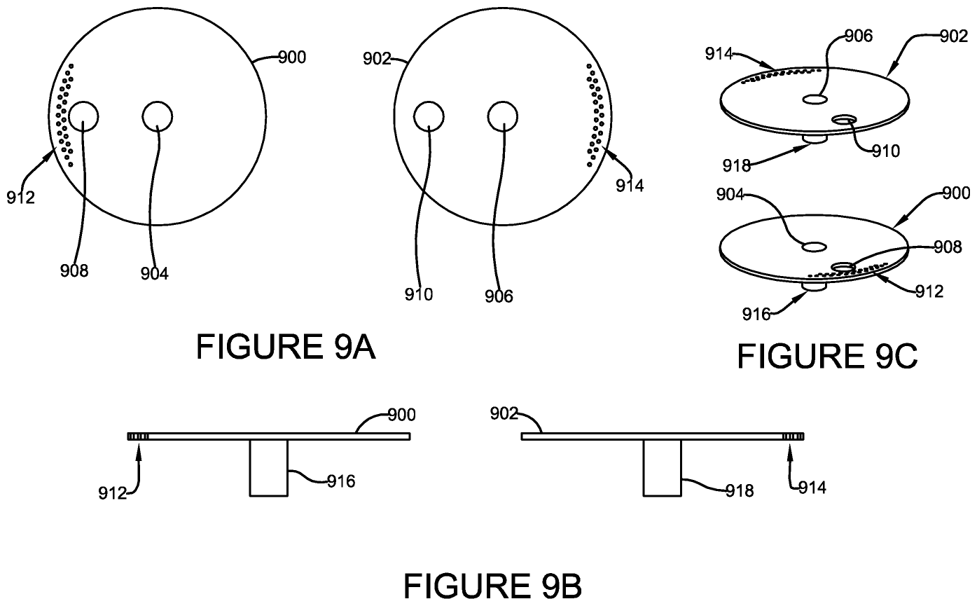

FIGS. 9A, 9B, and 9C are component diagrams illustrating example implementations where one or more portions of one or more apparatuses described herein may be implemented. In one implementation, a first channeling plane 900 can comprise one or more gas routing vias 912, which may be configured to allow passage of a carrier gas through the first channeling plane 900. Further, in one implementation, a second channeling plane 902 can be disposed in a bubbler container between the first channeling plane 900 and the top of the bubbling container. In this implementation, when the first channeling plane 900 is configured to direct a flow of the carrier gas from a first side of the bubbling container to a second side of the bubbling container, the second channeling plane 902 can be configured to direct the flow of the carrier gas from the second side of the bubbling container to the first side of said the bubbling container.

Further, in one implementation, the second channeling plane 902 can comprise one or more second gas routing vias 914 that may be configured to allow passage of the carrier gas through said second channeling plane 902. In one implementation, the one or more first gas routing vias 912 of the first channeling plane 900 can be disposed at the second side of the bubbling container, and the one or more second gas routing vias 914 of the second channeling plane 902 can be disposed at the first side of the bubbling container.

Additionally, in one implementation, the first channeling plane 900 can comprise at least one liquid passage via 904, and/or the second channeling plane 902 can comprise at least one liquid passage via 906. The liquid passage via 904, 906 can be configured to allow passage of the precursor liquid through the channeling planes 900, 902, such as during precursor liquid filling and/or after carrier gas flow is terminated and the liquid flows back to the bottom of the container. The liquid passage via 904, 906 can also be configured to mitigate passage of said gas through said first channeling plane, such as during carrier gas bubbling, for example.

In one implementation, the liquid passage via can comprise an extension component 916, 918 that can be disposed at a bottom portion of the channeling planes 900, 902. The extension component 916, 918 can be configured to facilitate passage of the precursor liquid through the channeling planes 900, 902, such as during precursor liquid filling and/or after carrier gas flow is terminated and the liquid flows back to the bottom of the container, for example, by guiding the liquid to another liquid passage via below. The extension component 916, 918 can also be configured mitigate passage of said gas through said first channeling plane, and/or the second channeling plane, such as during carrier gas bubbling, for example, where gas bubbles formed in the liquid may not be able to navigate through the extension component during bubbling.

In one embodiment, as illustrated in FIGS. 9A, 9B, and 9C, respective channeling planes 900, 902 may comprise a dip-tube through hole 908, 910, through which a dip-tube may be disposed. As an example, the dip-tube may provide and entry for the carrier gas, where the carrier gas in introduced through the dip-tube having an opening disposed at the bottom of the bubbler container (e.g., beneath the first channeling plane 900).

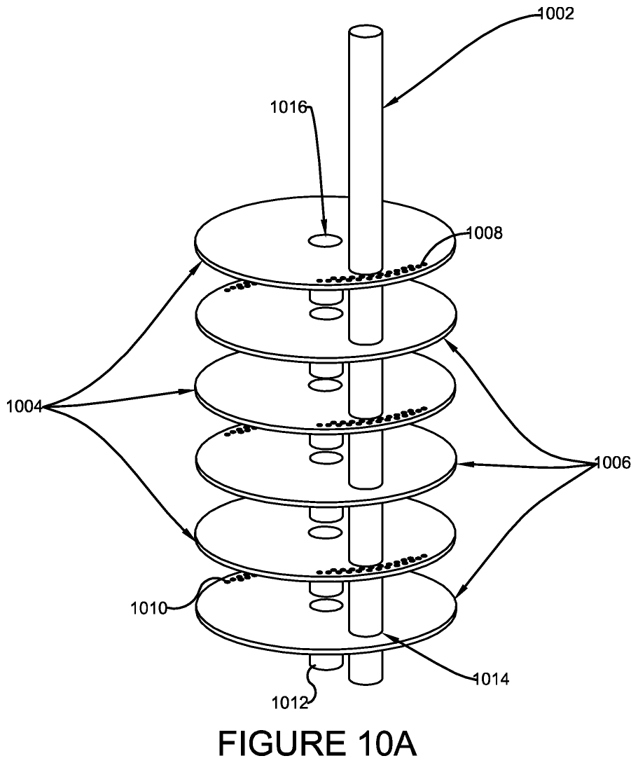

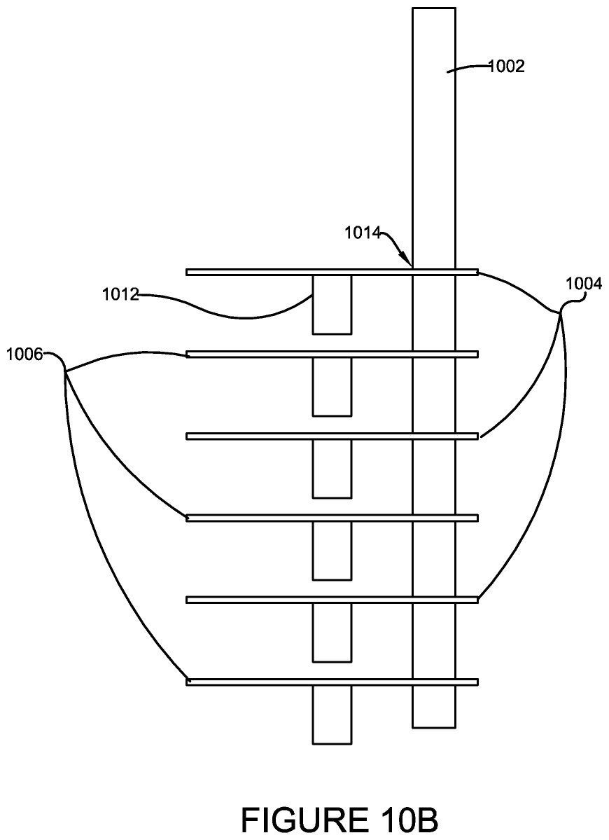

FIGS. 10A and 10B are component diagrams illustrating example implementations where one or more portions of one or more apparatuses described herein may be implemented. In one implementation, the dip-tube 1002 may be disposed through the respective channeling planes 1004, 1006 (e.g., through the dip-tube through hole 908, 910 of FIGS. 9A and 9C). In one implementation, one or more of the respective channeling planes 1004, 1006 may be sealed to the outside of the dip-tube 1002, for example, thereby creating a seal 1014 at the location where the dip-tube 1002 passes through the channeling plane 1004, 1006.

Further, as illustrated in FIGS. 10A and 10B, a system for saturating a gas with a liquid-borne compound may comprise a plurality of channeling planes 1004, 1006. In this implementation, a set of first channeling planes 1004 can comprise a set of one or more first gas routing vias 1010 at a second side of a bubbling container. Further, a set of second channeling planes 1006 can comprise a set of one or more second gas routing vias 1008 at a first side of a bubbling container. Additionally, respective channeling planes 1004, 1006 can comprise a liquid passage via 1016, further comprising an extension component 1012, disposed at the bottom portion of the respective channeling planes.

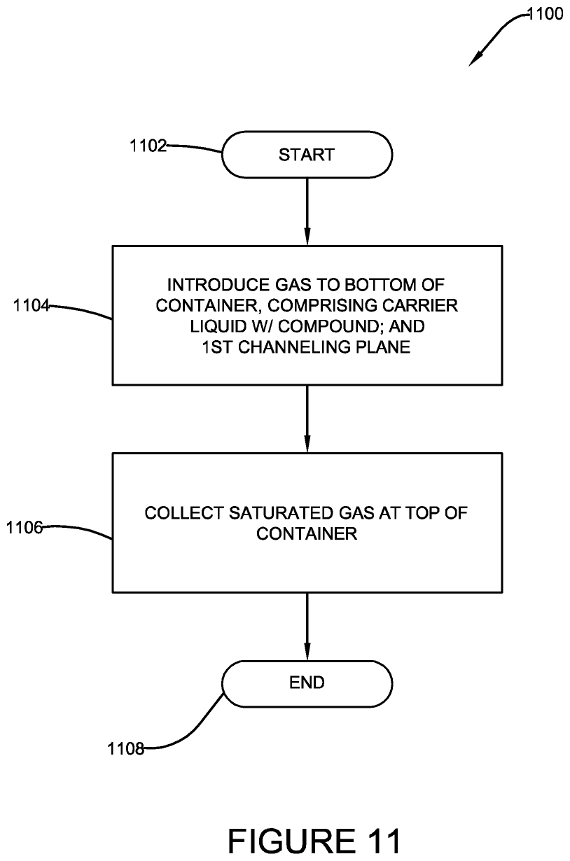

FIG. 11 is a flow diagram illustrating an exemplary method 1100 for saturating a gas with a liquid-borne compound. The exemplary method 1100 begins at step 1102. At step 1104, the gas (e.g., a carrier gas, such as H₂ or N₂) is introduced to the container at a bottom portion of the container. In this exemplary method 1100, the container comprises a carrier liquid that is configured to carry the liquid-borne compound (e.g., a desired saturation compound), and a first channeling plane disposed between the bottom of the container and the top of the container. At step 1106, the carrier gas (e.g., saturated with the desired compound) is collected at a top portion of the container. Having collected the gas, the exemplary method 1100 ends at step 1108.

In one implementation, a carrier gas (e.g., configured to carry a desired compound from the container to a secondary process), such as hydrogen or nitrogen, may be introduced to the bottom of the container using an inlet opening at the bottom portion of the container. In this implementation, for example, the inlet opening may be disposed below a liquid fill-line in the container, such that, when gas is introduced through the opening, the gas may be introduced into the liquid (e.g., forming gas bubbles in the liquid).

Further, in this implementation, the container can comprise a carrier liquid (e.g., configured to comprise the desired compound, and to effectively transfer the desired compound to the carrier gas during “bubbling”), such as a metalorganic compound (e.g., an indium based liquid). As an example, when the carrier gas is introduced to (e.g., bubbled through) the carrier liquid, the desired compound may be transferred (e.g., saturated) to the carrier gas, which may be collected at a gas outlet disposed at a top portion of the container.

In one implementation, the carrier gas may be introduced to a container that comprises a plurality of channeling planes (e.g., a first plane, second plane, third plane, etc.). In this implementation, the respective channeling planes may be disposed in an arrangement that creates a channeling route for carrier gas bubbles, initially formed at the bottom of the container. That is, for example, the carrier gas may be introduced at a first side of the container (e.g., at the bottom), and a first channeling plane may comprise a channel opening at a second side of the container. Further, a second channeling plane may comprise a channel opening at the first side of the container, and a third channeling plane may comprise a channel opening at the second side of the container (e.g., and so-on for additional channeling planes).

In this example, when the gas is introduced, bubbles formed at the first side can travel upward and may be forced to continue upward by flowing through the first channeling plane's channel opening at the second side. Further, in order to continue upward, for example, the bubbles may be forced to flow through the second channeling plane's channel opening at the first side, and so-on through the third channeling plane's channel opening at the second side. In this way, in this example, the carrier gas bubbles can be forced to flow in a circuitous route (e.g., the channeling route) through the container in order to reach the gas outlet at the top of the container. As an example, enabling the carrier gas to travel a longer route through the carrier liquid comprising the desired compound can facilitate improved saturation of the desired compound to the carrier gas, particularly at higher flow rates for the carrier gas.

In one implementation, the carrier gas may be introduced to a container that comprises one or more channeling planes, where one or more of the one or more channeling planes may comprise vias. In this implementation, the vias may be configured to merely allow passage of the carrier liquid through the via, while passage of a carrier gas bubble through the via can be mitigated. That is, for example, when the carrier gas is introduced to the carrier liquid, the gas bubbles may be forced to travel the channeling route created by the one or more channeling planes, while the carrier liquid may be able to travel upward in the container through both the channeling route and/or the vias.

When the carrier gas is introduced to the carrier liquid, for example, particularly at a higher gas flow rate, the gas bubbles can force the liquid to move upward in the container, where the bubble/liquid mix may move upward like the gas by itself. In one implementation, the gas bubbles may be forced through the channeling route because pressure in the channeling route is lower than pressure through the vias. In this implementation, for example, the liquid can be forced to move in the direction of the bubble flow (e.g., the channeling route); and, the liquid may also be forced through the vias, thereby providing additional liquid to gas bubble exposure time.

In one implementation, when the carrier gas flow is shut off (e.g., using a shut of valve at the inlet and/or the outlet), the carrier liquid that may have been forced upward in the container may drain back down the bottom of the container. As an example, the disposition of the one or more vias in the one or more channeling planes may facilitate in draining of the liquid back down to the bottom. That is, for example, the liquid can flow back through a via from a top of a channeling plane to a bottom of the channeling plane, thereafter collecting at the bottom of the container (e.g., to a main carrier liquid reservoir).

Various operations of implementations are provided herein. The order in which some or all of the operations are described should not be construed as to imply that these operations are necessarily order dependent. Alternative ordering will be appreciated by one skilled in the art having the benefit of this description. Further, it will be understood that not all operations are necessarily present in each implementation provided herein.

Moreover, the word “exemplary” is used herein to mean serving as an example, instance or illustration. Any aspect or design described herein as “exemplary” is not necessarily to be construed as advantageous over other aspects or designs. Rather, use of the word exemplary is intended to present concepts in a concrete fashion. As used in this application, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Further, At least one of A and B and/or the like generally means A or B or both A and B. In addition, the articles “a” and “an” as used in this application and the appended claims may generally be construed to mean “one or more” unless specified otherwise or clear from context to be directed to a singular form.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

Also, although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. Furthermore, to the extent that the terms “includes,” “having,” “has,” “with,” or variants thereof are used in either the detailed description or the claims, such terms are intended to be inclusive in a manner similar to the term “comprising.”

The implementations have been described, hereinabove. It will be apparent to those skilled in the art that the above methods and apparatuses may incorporate changes and modifications without departing from the general scope of this invention. It is intended to include all such modifications and alterations in so far as they come within the scope of the appended claims or the equivalents thereof.

What is claimed is:

1. A system for saturating a gas with a liquid-borne compound, comprising:
a containment component configured to:
contain a carrier liquid comprising a compound; and
allow a gas to enter said containment component at a bottom portion of said containment component, flow through said liquid and exit said containment component at a top portion of said containment component;
said containment component comprising a first channeling plane disposed between the bottom of said containment component and the top of said containment component.

2. The system of claim 1, wherein said first channeling plane comprises one or more gas routing vias configured to allow passage of said gas through said first channeling plane.

3. The system of claim 1, wherein said containment component further comprises a second channeling plane disposed between said first channeling plane and the top of said containment component, said first channeling plane configured to direct a flow of said gas from a first side of said containment component to a second side of said containment component, and said second channeling plane configured to direct said flow of said gas from said second side of said containment component to said first side of said containment component.

4. The system of claim 3, wherein said first channeling plane comprises one or more first gas routing vias configured to allow passage of said gas through said first channeling plane, and said second channeling plane comprises one or more second gas routing vias configured to allow passage of said gas through said second channeling plane;
wherein:
said one or more first gas routing vias are disposed at said second side of said containment component; and
said one or more second gas routing vias are disposed at said first side of said containment component.

5. The system of claim 1, wherein said first channeling plane comprising at least one liquid passage via configured to perform one or more of:
allow passage of said liquid through said first channeling plane; and
mitigate passage of said gas through said first channeling plane.

6. The system of claim 5, wherein said liquid passage via comprises an extension component, disposed at a bottom portion of said first channeling plane, configured to perform one or more of:
facilitate passage of said liquid through said first channeling plane; and
mitigate passage of said gas through said first channeling plane.

7. The system of claim 1, wherein said first channeling plane is sealed to an outside of a dip-tube, wherein said dip-tube extends through said first channeling plane to the bottom portion of said containment component.

8. A device for saturating a gas with a liquid-borne compound, comprising:
a containment component configured to:
contain a carrier liquid comprising a compound; and
allow a gas to enter said containment component at a bottom portion of said containment component, flow through said liquid and exit said containment component at a top portion of said containment component;
said containment component comprising:
at least a first channeling plane disposed between the bottom of said containment component and the top of said containment component; and
a dip-tube extending through at least said first channeling plane, wherein the outside of said dip-tube is engaged with at least said first channeling plane at a first plane dip-tube through a first via.

9. The device of claim 8, wherein said containment component further comprises a second channeling plane disposed between the said first channeling plane and the top of said containment component, wherein the outside of said dip-tube is engaged with said second channeling plane at a second plane dip-tube through a second via.

10. The device of claim 8, wherein said containment component further comprises a plurality of second channeling planes disposed between the said first channeling plane and the top of said containment component, wherein the outside of said dip-tube is engaged with respective plurality of second channeling planes at a second plane dip-tube through a second via disposed in respective plurality of second channeling planes.

11. The device of claim 8, wherein said engagement of the outside of said dip-tube with at least said first channeling plane at said first plane dip-tube through the first via comprises a sealed engagement that mitigates gas leakage at said engagement.
